(19) United States
(12) Patent Application Publication
(10) Pub. No.: US 2020/0411466 A1
(43) Pub. Date: Dec. 31, 2020

(54) THERMOCOMPRESSION BONDING DEVICE

(71) Applicant: SAKAI DISPLAY PRODUCTS CORPORATION, Sakai-shi, Osaka (JP)

(72) Inventor: YOHICHIROH SAKAKI, Sakai-shi, Osaka (JP)

(21) Appl. No.: 16/976,280

(22) PCT Filed: Mar. 12, 2018
(86) PCT No.: PCT/JP2018/009525

§ 371 Date: Aug. 27, 2020

(51) Int. Cl. H01L 23/00; G02F 1/1345; B32B 37/02; B32B 37/10; B32B 37/06

(52) U.S. Cl. CPC H01L 24/79; B32B 2457/20; H01L 24/86; H01L 24/83; H01L 24/92; B32B 37/02; B32B 37/10; B32B 37/06; H01L 2224/79252; H01L 2224/79251; H01L 2224/79985; H01L 2224/79988; H01L 2224/7931; H01L 2224/9211; H01L 2224/83203; H01L 2224/83851; H01L 2224/86203; G02F 1/13452

(57) ABSTRACT

This thermocompression bonding device is provided with a heating tool (1) and a backup member (3). The backup member (3) has: a support portion (3a) which faces the tip (1a) of the heating tool (1) while first and second members (111, 122) to be joined and a cushioning member (2) are located therebetween, and which supports the first and second members (111, 122) to be joined; and a body portion (3b) provided on the opposite side of the support portion (3a) from the first and second members (111, 122) to be joined. The support portion (3a) is formed so that the heat conductivity thereof is lower than that of the body portion (3b).

### TECHNICAL FIELD

The invention relates to a thermocompression bonding apparatus to be used for thermocompression bonding of a member to be joined.

### BACKGROUND ART

A conventional thermocompression bonding apparatus comprises a heating tool; and a backup member being arranged under this heating tool (see JP 2015-197570 A (Patent Document 1), for example). In a case that thermocompression bonding is carried out with this thermocompression bonding apparatus, a first member to be joined and a second member to be joined are sandwiched between the heating tool and the backup member. Here, the first member to be joined and the second member to be joined are put on top of each other via an anisotropic conductive film. In this state, the heater in the heating tool is caused to generate heat to heat the anisotropic conductive film. This causes a terminal of a wiring being provided in the first member to be joined to be electrically connected, via the anisotropic conductive film, to a terminal of a wiring being provided in the second member to be joined.

### PRIOR ART DOCUMENT

### Patent Document

Patent Document 1: JP 2015-197570 A

### SUMMARY OF THE INVENTION

### Problem to be Solved by the Invention

Now, in the above-described conventional thermocompression bonding apparatus, an anisotropic conductive film needs to be heated for 5 to 6 seconds at approximately 200° C. In this case, the setting temperature of the above-mentioned heating tool needs to be set to be greater than or equal to 350° C.

However, a problem arises that setting the setting temperature of the heating tool to be greater than or equal to 350° C. causes the heating tool to be deformed.

Moreover, a problem also arises that in a case where a member susceptible to heat is mounted to the first member to be joined or the second member to be joined, such a member is thermally damaged.

Thus, a problem to be solved by the invention is to provide a thermocompression bonding apparatus that can suppress deformation of a heating tool and also reduce thermal damage of a low heat-resistant member.

### Means to Solve the Problem

A thermocompression bonding apparatus according to one aspect of the invention is a thermocompression bonding apparatus to thermocompression bond a second member to be joined to a first member to be joined, the thermocompression bonding apparatus comprising:

a heating tool to heat the first member to be joined and the second member to be joined, the heating tool comprising a tip to be pressed toward the first and second members to be joined;

a cushioning member being arranged between the first and second members to be joined and the tip of the heating tool; and

a backup member, wherein

the backup member comprises:

a support portion to support the first member to be joined and the second member to be joined, the support portion facing the tip of the heating tool via the first member to be joined, the second member to be joined, and the cushioning member; and

a body portion being provided opposite to the first member to be joined and the second member to be joined with respect to the support portion, and

the support portion is formed such that a heat conductivity of the support portion is brought to be less than a heat conductivity of the body portion.

### Effects of the Invention

A thermocompression bonding apparatus according to the invention can suppress deformation of a heating tool and also reduce thermal damage of a low heat-resistant member.

### BRIEF DESCRIPTION OF THE DRAWINGS

FIG. 1 schematically shows a cross-sectional view of the main part of a thermocompression bonding apparatus according to one embodiment of the invention.

FIG. 2 schematically shows a plan view of a liquid crystal display panel.

FIG. 3 schematically shows a plan view of a source COF.

FIG. 4 schematically shows a plan view to explain thermocompression bonding by the above-mentioned thermocompression bonding apparatus.

FIG. 5 schematically shows a cross-sectional view to explain thermocompression bonding by the above-mentioned thermocompression bonding apparatus.

FIG. 6 shows a graph on the relationship between the connection temperature and L/λ.

FIG. 7 shows a graph on the relationship between the temperature difference and Lcρ/λ.

FIG. 8 shows a graph of the temperature change with time of an anisotropic conductive film and the temperature change with time of a support portion of a backup member.

FIG. 9 shows another graph of the temperature change with time of the anisotropic conductive film and the temperature change with time of the support portion of the backup member.

FIG. 10 shows another graph of the temperature change with time of the anisotropic conductive film and the temperature change with time of the support portion of the backup member.

FIG. 11 shows a graph of the temperature change with time of the anisotropic conductive film.

FIG. 12 shows another graph of the temperature change with time of the anisotropic conductive film.

### EMBODIMENT FOR CARRYING OUT THE INVENTION

Below, a thermocompression bonding apparatus of the invention is explained in more detail according to embodiments illustrated. In the drawings, identical reference numbers represent identical or corresponding portions.

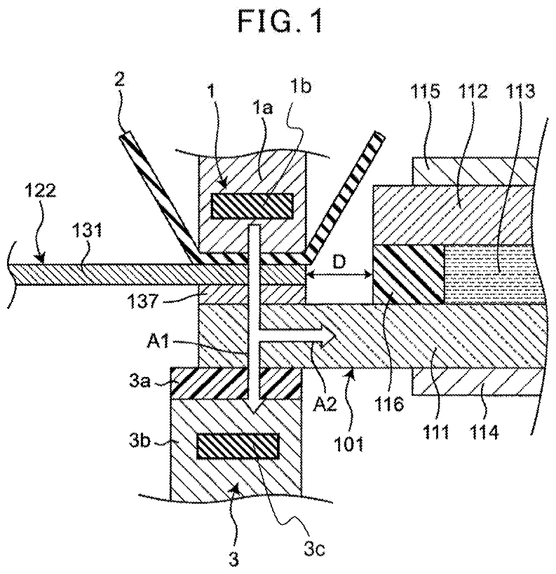

FIG. 1 schematically shows a cross-sectional view of the main part of a thermocompression bonding apparatus according to one embodiment of the invention.

The thermocompression bonding apparatus comprises a heating tool 1, a cushion sheet 2 as one example of a cushioning member, and a backup member 3 and thermocompression bonds a liquid crystal display panel 101 and a source COF (chip on film) 122. A TFT substrate 111 of the liquid crystal display panel 101 is one example of a first member to be joined. Moreover, the source COF 122 is one example of a second member to be joined.

The heating tool 1 comprises a tip 1a to be pressed toward where the liquid crystal display panel 101 and the source COF 122 are present, or, in other words, downward in FIG. 1 and heats the liquid crystal display panel 101 and the source COF 122. Explaining in more detail, the heating tool 1 is formed with a metal, for example, and has a rectangular parallelepiped shape, embedding a heater (not shown) therein.

The cushion sheet 2 is to alleviate collision with the heating tool 1 and the source COF 122. Explaining in more detail, the cushion sheet 2 is set to have the thickness of 0.2 [mm], for example, and comprises a heat-resistant and elastic material (for example, silicone rubber). Such a rubber sheet is stretched between two reels (not shown) in a tension-applied state and a part thereof is arranged between the heating tool 1 and the backup member 3. Moreover, it is possible to bring a new portion or, in other words, a clean portion of the rubber sheet into contact with the source COF 122 by winding up the cushion sheet 2 with the above-mentioned reel.

The backup member 3 comprises a support portion 3a being positioned toward the heating tool 1 and a body portion 3b being positioned opposite to the heating tool 1.

The support portion 3a faces the tip 1a of the heating tool 1 via the cushion sheet 2, the source COF 122, and the TFT substrate 111. The tip surface (the surface to be in contact with the TFT substrate) of this support portion 3a is a flat surface. Moreover, when the heating tool 1 pressurizes the source COF 122 and the TFT substrate 111, the tip 1a of the heating tool 1 and the support portion 3a of the backup member 3 sandwiches the source COF 122 and the TFT substrate 111. Furthermore, the support portion 3a comprises phenolic resin as one example of a heat-resistant resin, the heat conductivity of the support portion 3a is lower than that of the backup member 3.

Moreover, assuming that the thickness of the support portion 3a is L [m], the heat conductivity of the support portion 3a is [W/(m·K)], the specific heat of the support portion 3a is c [J/(kg·K)], and the density of the support portion 3a is p [kg/m³], the below-described formulas (1) and (2) are satisfied.

L/λ≥0.004 (1)

Lcρ/λ≤80000 (2)

The settings in which the above-described formulas (1) and (2) are satisfied include the setting in which the thickness L of the support portion 3a is set to be 0.001 [m], the heat conductivity λ of the support portion 3a is set to be 0.19 [W/(m·K)], the specific heat c of the support portion 3a is set to be 1665 [J/(kg·K)], and the density ρ of the support portion 3a is set to be 1275 [kg/m³], for example.

While the thickness L of the support portion 3a can be set to have a value other than 0.001 [m], or, in other words, 1 [mm], it is preferably set to be within a range of 1 [mm] to 2 [mm], for example, from the viewpoint of decreasing the amount of heat to be moved away from the heating tool 1 toward the backup member 3 and the viewpoint of suppressing the increase in the amount of heat to be stored in the support portion 3a.

The body portion 3b comprises a material (for example, a metal), having the heat conductivity being higher than that of phenolic resin, and has a rectangular parallelepiped shape. The support portion 3a is fixed to the tip surface of this body portion 3b with an adhesive agent, for example. Moreover, the body portion 3b embeds therein a heater (not shown) similarly to the heating tool 1.

Furthermore, while not shown, the thermocompression bonding apparatus comprises a drive mechanism to drive the heating tool 1 in upward/downward directions and a stage to allow position adjustment in the horizontal direction with the liquid display panel 101 being mounted thereto. This drive mechanism drives the heating tool 1 in the upward/downward directions, thereby adjusting the interval between the tip 1a of the heating tool 1 and the backup member 3. As one example of the drive mechanism, an air cylinder, for example, is used.

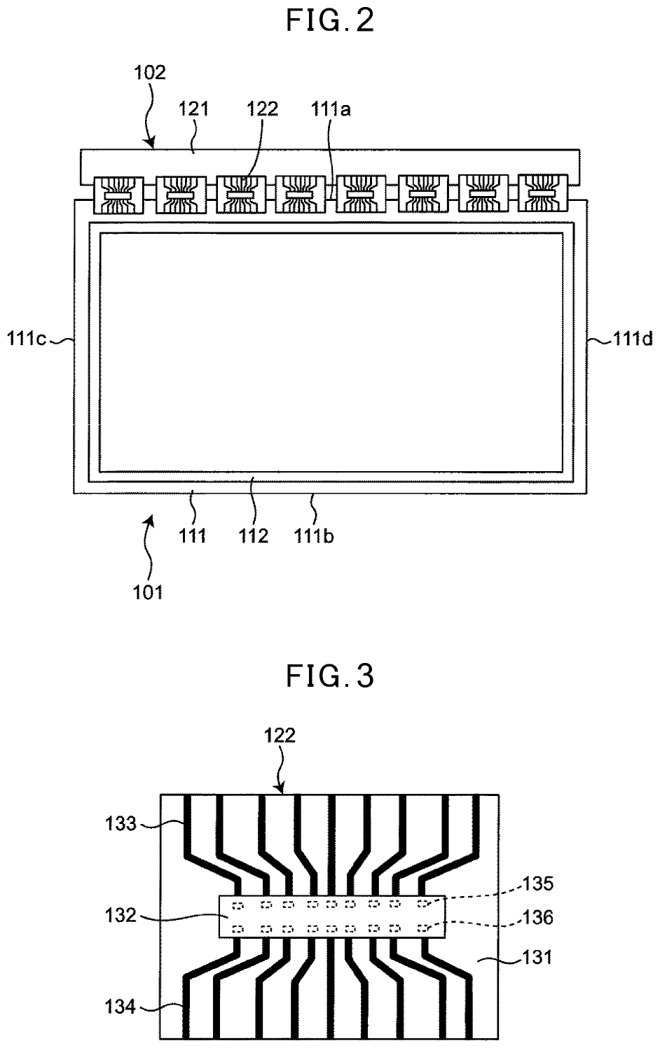

FIG. 2 schematically shows a view from the above of the liquid crystal display panel 101 for which the thermocompression bonding apparatus is used.

The liquid crystal display panel 101 is a 60-inch or 70-inch liquid crystal display panel, for example, and comprises a TFT (thin-film transistor) substrate 111; and a color filter substrate 112 being arranged so as to face this TFT substrate 111. Each of the TFT substrate 111 and color filter substrate 112 has a planer view shape being rectangular. Moreover, a liquid crystal layer 113 (shown in FIG. 1) is sandwiched between the TFT substrate 111 and the color filter substrate 112. Furthermore, a sealing material 116 to seal the liquid crystal layer 113 is provided between the TFT substrate 111 and the color filter substrate 112.

The TFT substrate 111 has long sides 111a, 111b extending along the left-right directions in FIG. 2 and facing each other and short sides 111c, 111d along the upward-downward directions in FIG. 2 and facing each other. In other words, in a planar view, the TFT substrate 111 has a rectangular shape. Moreover, while not shown, the TFT substrate 111 comprises a plurality of TFTs being arranged in a matrix; a plurality of gate wirings; and a plurality of source wirings to cross with the plurality of gate wirings. The TFT substrate 111 can have a planer view being a square.

The plurality of gate wirings are parallel with each other and extend in the row direction. Here, the row direction coincides with the direction along the long sides 111a, 111b of the TFT substrate 111.

The plurality of source wirings are parallel with each other and extend in the column direction. Here, the column direction coincides with the direction along the short sides 111c, 111d of the TFT substrate 111.

Each of the TFTs is electrically connected to the gate wiring and the source wiring, and controls the voltage to be applied to a pixel electrode. The terminal of each of the source wirings is formed on the edge toward the long side 111a at the upper surface of the TFT substrate 111.

Moreover, a first polarizing plate 114 (shown in FIG. 1) is bonded to the lower surface of the TFT substrate 111.

While not shown, the color filter substrate 112 comprises color filters and a common electrode toward the TFT substrate 111. The color filters comprise a plurality of red color filters, a plurality of green color filters, and a plurality of blue color filters. Each of the red color filters, each of the green color filters, and each of the blue color filters correspond to a red sub-pixel, a green sub-pixel, and a blue sub-pixel, respectively. The color filters can comprise, in a plurality, at least one of a yellow color filter and a white color filter.

Furthermore, a second polarizing plate 115 having the polarizing axis being orthogonal to the polarizing axis (the transmitting axis) of the first polarizing plate 114 is bonded to the upper surface of the color filter substrate 112.

Moreover, the liquid crystal display panel 101 comprises the source driver 102 toward the long side 111a of the TFT substrate 111. This source driver 102 comprises a printed substrate 121 extending along the longitudinal direction of the TFT substrate 111 and a plurality of source COFs 122, 122, . . . , 122. While not shown, a plurality of wirings (below called “source signal wirings”) through which a source signal is input is formed on the upper surface of the printed substrate 121. Furthermore, each of the source COFs 122 is stretched between the printed substrate 121 and the TFT substrate 111. The number of source COFs 122, 122, . . . , 122 is to be changed in accordance with the size of the liquid crystal display panel 101, so that it is construed to be not particularly limited. Moreover, the source COF is a flexible printed wiring board manufactured using a COF tape.

Furthermore, an IC (integrated circuit) chip (not shown) to output a gate signal to the gate wiring is directly formed on the upper surface of the TFT substrate 111. In a case that the IC chip is not used, a gate driver being the same as the source driver 102 can be mounted to at least one of the edge toward the short side 111c of the TFT substrate 111 and the edge toward the short side 111d of the TFT substrate 111, for example.

FIG. 3 schematically shows the source COF 122 from the above.

The source COF 122 comprises: a film base material 131; a source driver IC 132 being mounted to the front surface of the film base material 131; a plurality of input wirings 133, 133, . . . , 133 being formed on the upper portion in FIG. 3 of the front surface of the film base material 131; and a plurality of output wirings 134, 134, . . . , 134 being formed on the lower portion in FIG. 3 of the front surface of the film base material 131. In FIG. 1, the front surface of the film base material 131 is oriented toward the lower side while the rear surface of the film base material 131 is oriented toward the upper side.

The film base material 131 is formed with a polyimide-based resin, for example, so as to have a rectangular shape in the planar view. The film base material 131 can have a square shape in the planar view.

The source driver IC 132 is a semiconductor chip being mounted to the film base material 131 using a COF mounting technique. A plurality of input terminals 135 are provided at an input side portion of the source driver IC 132. On the other hand, a plurality of output terminals 136 are provided at an output side portion of the source driver IC 132. Each of the plurality of input terminals 135 and the plurality of output terminals 136 forms a line along the long side of the film base material 131.

Each input wiring 133 extends toward the input terminal 135 of the source driver IC 132 from the input side edge of the film base material 1. Moreover, the input side end of each input wiring 133 (being opposite to the source driver IC 132) is electrically connected to the source signal wiring of the printed substrate 121. On the other hand, the output side end of each input wiring 133 (toward the source IC 132) is in electrical conduction with the input terminal 135 of the source driver IC 132.

The input side end of each output wiring 134 (toward the source driver IC 132) is in electrical conduction with the output terminal 136 of the source driver IC 132. On the other hand, the output side end of each output wiring 134 (being opposite to the source driver IC 132) is electrically connected to the terminal of the source wiring of the TFT substrate 111 via a below-described anisotropic conductive film 137. While the number of output wirings 134 is drawn to be the same as the number of input wirings 133 in FIG. 3, it is normally greater than the number of input wirings 133.

Below, a method of thermocompression bonding the source COF 122 to the TFT substrate 111 of the liquid crystal display 101 using a thermocompression bonding apparatus according to the above-described configuration is explained.

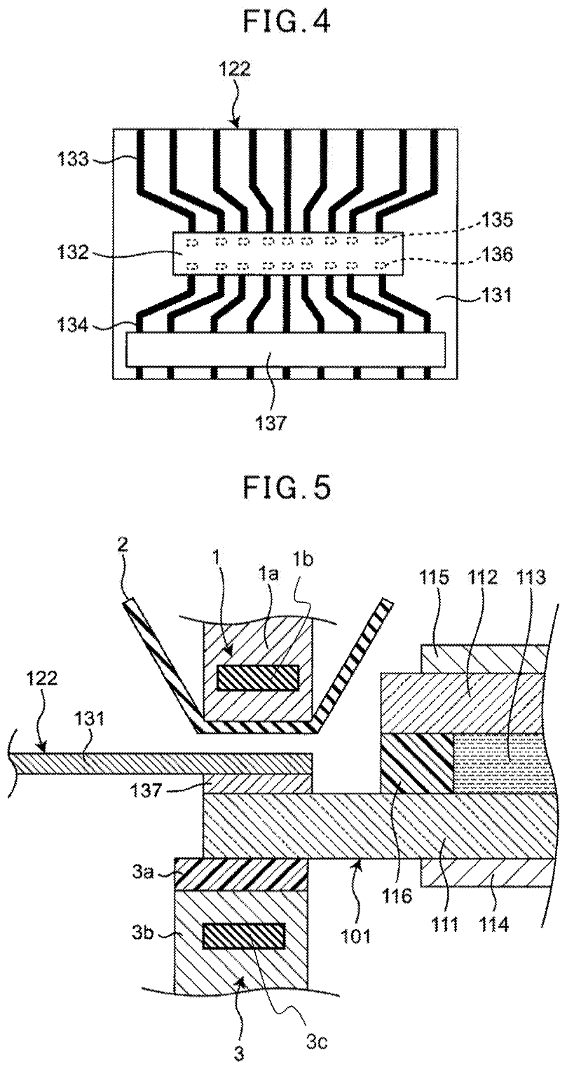

First, as shown in FIG. 4, the anisotropic conductive film 137 is bonded to the upper surface of the film base material 131 to cover the output side end of each output wiring 134 with the anisotropic conductive film 137. This anisotropic conductive film 137 is formed into a sheet shape with conductive particles of nickel or solder, for example, being dispersed in a thermosetting resin, for example.

Next, as shown in FIG. 5, the output side end of the source COF 122 is arranged between the heating tool 1 and the backup member 3 such that the output side end of the output wiring 134 being provided to the source COF 122 is positioned on the terminal of the source wiring being provided to the TFT substrate 111. Here, the cushion sheet 2 is present over the output side end of the source COF 122. On the other hand, the anisotropic conductive film 137 is present under the output side end of the source COF 122.

Next, as shown in FIG. 1, the previously described drive mechanism is driven to lower the heating tool 1 to press the output side end of the source COF 122 against the edge part of the TFT substrate 111 to pressurize the output side end of the source COF 122 at a predetermined pressure. Here, the support portion 3a of the backup member 3 makes a contact with the lower surface of the TFT substrate 111, so that the source COF 122 and the TFT substrate 111 are sandwiched. Moreover, the cushion sheet 2 is elastically deformed to be brought into a close contact with the rear surface of the film base material 131 of the source COF 122.

Next, current is provided to a heater in the heating tool 1 and the temperature of the heating tool 1 is controlled such that the temperature of the anisotropic conductive film 137 is brought to be approximately 200° C. The state in which the temperature of the anisotropic conductive film 137 is brought to be approximately 200° C. is maintained for 5 to 6 seconds, for example. This causes the resin in the anisotropic conductive film 137 to be softened and crushed. When the current is provided to the heater in the heating tool 1, current is also provided to a heater in the backup member 3 and the temperature of the body portion 3b of the backup member 3 is maintained to approximately 80° C., for example.

Thereafter, the drive mechanism is driven to raise the heating tool 1 and the source COF 122 and the TFT substrate 111 are taken out from in between the heating tool 1 and the backup member 3.

The process as described in the above causes heat and pressure to be applied to the anisotropic conductive film 137, the edge of the TFT substrate 111 and the output side end of the source COF 122 are mechanically connected, and the terminal of the source wiring and the output side end of the output wiring 134 are electrically connected.

Furthermore, in a case that the anisotropic conductive film 137 is heated with the heating tool 1, the amount of heat to move along the arrow A2 toward the liquid crystal display panel 101 from the heating tool 1 does not change generally compared to a case in which the backup member 3 does not comprise the support portion 3a. On the other hand, the amount of heat to move along the arrow A1 toward the backup member 3 from the heating tool 1 is less compared to a case in which the backup member 3 does not comprise the support portion 3a. Therefore, while the setting temperature of the heating tool 1 is set to be lower compared to the case in which the backup member 3 does not comprise the support portion 3a, the temperature of the anisotropic conductive film 137 can be brought to approximately 200° C. Therefore, it is not necessary to set the temperature of the heating tool 1 high, making it possible to suppress deformation of the heating tool 1.

In recent years, due to narrowing of frame of the liquid crystal display panel 101, a distance D between the heating tool 1 and the sealing material 116 may be set to fall between 0.3 [mm] and 0.4 [mm], for example. In such circumstances, a temperature increase in the heating tool 1 causes a significant adverse effect on the first and second polarizing plates 114, 115 having a low heat resistance. According to the present embodiment, it is not necessary to set the temperature of the heating tool 1 high, therefore, it is possible to reduce the adverse effect on the first and second polarizing plates 114, 115.

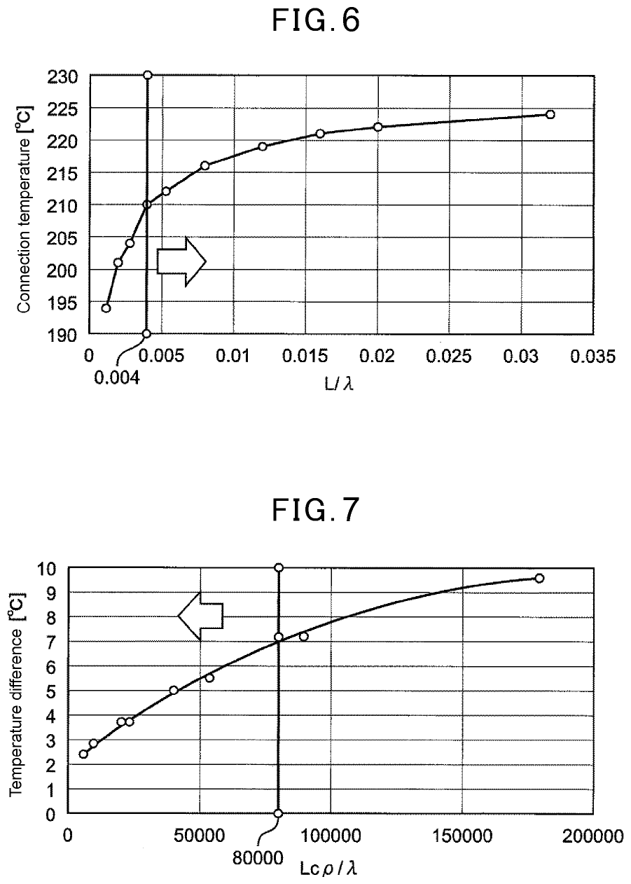

FIG. 6 is a graph showing the relationship between the connection temperature and La Here, the connection temperature refers to the temperature of the anisotropic conductive film 137. When data for the graph was obtained, the setting temperature of the heating tool 1 was set to be 290*C, the setting temperature of the body portion 3b of the backup member 3 was set to be approximately 80° C., and a silicone rubber sheet having the thickness of 0.2 [mm] was used as the cushion sheet 2.

As clear from FIG. 6, the temperature of the anisotropic conductive film 137 changes when L/λ is changed even though the heating time of the anisotropic conductive film 137 is kept the same. Here, when L/λ is greater than or equal to 0.004, the temperature of the anisotropic conductive film 137 never falls below 200° C. Therefore, with forming the support portion 3a of the backup member 3 so as to satisfy the above-described Equation (1), it is possible to surely bring the temperature of the anisotropic conductive film 137 to greater than or equal to 200° C. without increasing the heating time of the anisotropic conductive film 137.

The temperature of the anisotropic conductive film 137 is managed while taking into account an error of ±10° C. In other words, the target temperature is set such that there is no problem even when the actual temperature of the anisotropic conductive film 137 deviates by ±10° C. from the target temperature. Specifically, the target temperature is set to be 210° C. so as to not fall below the lower-limit temperature of 200° C. and to not rise above the upper-limit temperature of 220° C. Therefore, 0.004 corresponding to the connection temperature of 210° C. is set to be the lower limit.

FIG. 7 is a graph showing the relationship between the temperature difference and Lcρ/λ. Here, the temperature difference refers to a difference between a temperature of the anisotropic conductive film 137 at the first thermocompression bonding and a temperature of the anisotropic conductive film 137 at the 15th thermocompression bonding at which the temperature variation is generally eliminated when thermocompression bonding is carried out a plurality of times with the thermocompression bonding apparatus. When data for the graph was obtained, the setting temperature of the heating tool 1 was set to be 290° C., the setting temperature of the body portion 3b of the backup member 3 was set to be approximately 80° C., and a silicone rubber sheet having the thickness of 0.2 [mm] was used as the cushion sheet 2.

As clear from FIG. 7, with bringing Lcρ/λ to be less than or equal to 80000, it is possible to decrease the temperature variation of the anisotropic conductive film 137. Conversely, when Lcρ/λ exceeds 80000, the temperature variation of the anisotropic conductive film 137 increases; therefore, it is need to adjust the setting temperature of the heating tool 1 every time the above-described thermocompression bonding process is carried out.

As described in the above, the temperature of the anisotropic conductive film 137 is managed while taking into account an error of ±10° C. Here, the temperature variation of the anisotropic conductive film 137 is affected not only by the backup member 3, but also by the other elements (such as the thickness variation of each material). According to the embodiment, the error due to the effect of the other elements is set to be 3° C. and, to bring the temperature variation due to the effect of the backup member 3 to be less than or equal to approximately 7° C., Lcρ/λ≤80000.

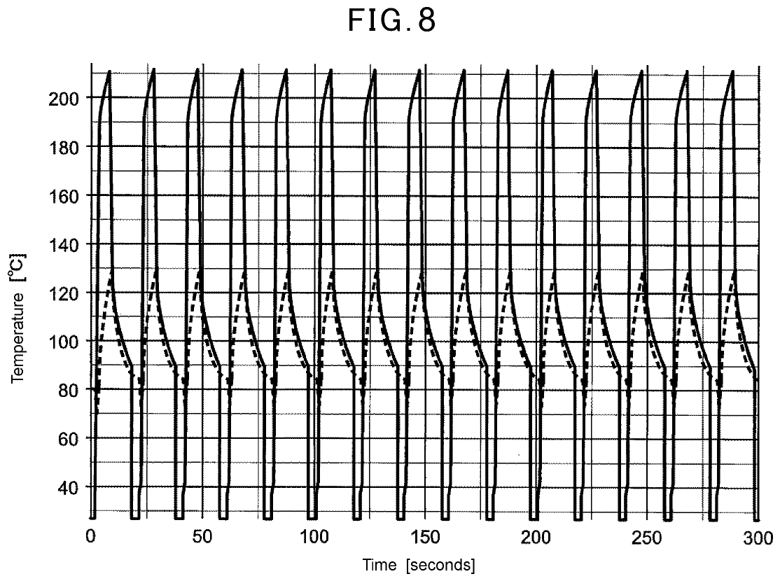

The difference arising from changing Lcρ/λ is described in more detail using FIGS. 8 to 10.

FIG. 8 shows, in a solid line, the temperature change with time of the anisotropic conductive film 137 and shows, in a dotted line, the temperature change with time of the support portion 3a of the backup member 3 when the above-described thermocompression bonding process is carried out a plurality of times with Lcρ/λ being set to have the value at the time when the detection point at the left end in the graph in FIG. 7 is detected.

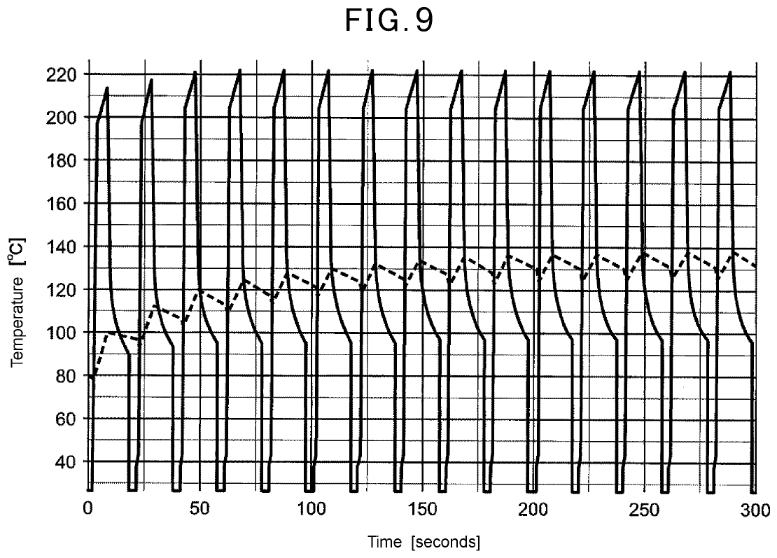

FIG. 9 shows, in a solid line, the temperature change with time of the anisotropic conductive film 137 and shows, in a dotted line, the temperature change with time of the support portion 3a of the backup member 3 when the above-described thermocompression bonding process is carried out a plurality of times with Lcρ/λ being set to have the value at the time when the detection point at the right end in the graph in FIG. 7 is detected.

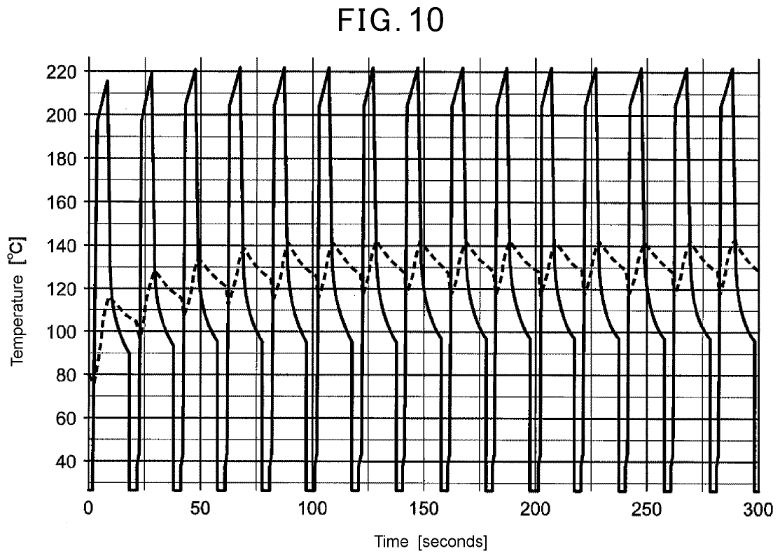

FIG. 10 shows, in a solid line, the temperature change with time of the anisotropic conductive film 137 and shows, in a dotted line, the temperature change with time of the support portion 3a of the backup member 3 when the above-described thermocompression bonding process is carried out a plurality of times with Lcρ/λ being set to be 80000.

While the temperature after the thermocompression bonding process of the support portion 3a of the backup member 3 possibly does not fall all the way down to the temperature before the thermocompression bonding process in the early period (0 [seconds] to 100 [seconds]) of the thermocompression bonding process when Lcρ/λ is less than or equal to 80000 as shown in FIGS. 8 and 10, it is possible to surely bring the temperature after the thermocompression bonding process of the support portion 3a of the backup member 3 down to the temperature before the thermocompression bonding process in the middle period (100 [seconds] to 200 [seconds]) and the late period (200 [seconds] to 300 [seconds]) of the thermocompression bonding process. In other words, a continuous temperature increase of the support portion 3a of the backup member 3 can be suppressed.

In contrast, when Lcρ/λ exceeds 80000, the temperature after the thermocompression bonding process of the support portion 3a of the backup member 3 possibly does not fall all the way down to the temperature before the thermocompression bonding process not only in the early period (0 [seconds] to 100 [seconds]) of the thermocompression bonding process, but also in the middle period (100 [seconds] to 200 [seconds]) and the late period (200 [seconds] to 300 [seconds]) of the thermocompression bonding process as shown in FIG. 9, causing the temperature of the support portion 3a of the backup member 3 to continuously increase.

In this way, with setting Lcρ/λ to be less than or equal to 80000, it is possible to suppress a continuous temperature increase of the support portion 3a of the backup member 3 when the thermocompression bonding process is carried out a plurality of times.

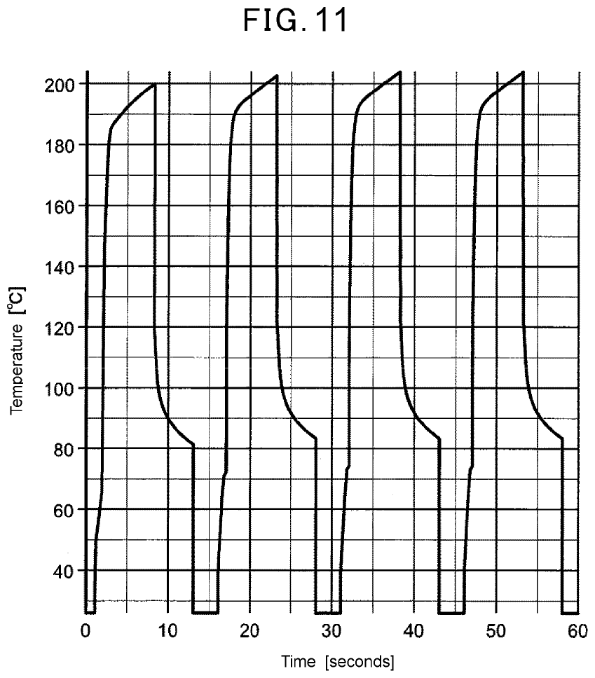

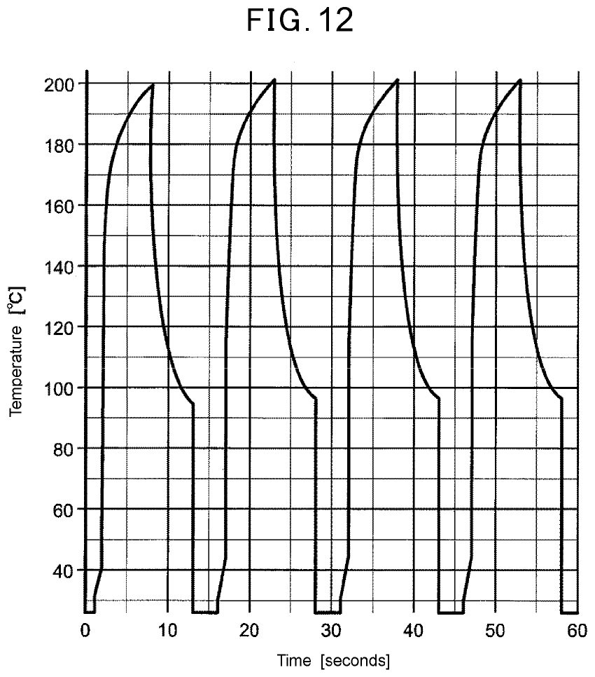

FIGS. 11 and 12 are graphs showing the temperature change with time of the anisotropic conductive film 137. The graph in FIG. 11 shows a case in which the backup member 3 does not comprise the support portion 3a. On the other hand, FIG. 12 shows a case in which the backup member 3 comprises the support portion 3a.

In a case that the backup member 3 does not comprise the support portion 3a and supports the edge of the TFT substrate 111 with the body portion 3b, it is necessary to set the setting temperature of the heating tool 1 to be approximately 350° C. and set the setting temperature of the body portion 3b of the backup member 3 to be approximately 80° C. to carry out a thermocompression bonding process four times in 60 seconds. In a case that the backup member 3 does not comprise the support portion 3a, the setting temperature of the heating tool 1 can be set to be approximately 350° C. and the setting temperature of the body portion 3b of the backup member 3 can be set to be approximately 80° C. to heat the anisotropic conductive film 137 for 5 to 6 seconds at approximately 200° C. for each thermocompression bonding process as shown in FIG. 11.

In contrast, in a case that the backup member 3 comprises the support portion 3a, the setting temperature of the heating tool 1 can be set to be approximately 270° C. and the setting temperature of the body portion 3b of the backup member 3 can be set to be approximately 80° C. to carry out a thermocompression bonding process four times in 60 seconds. In a case that the backup member 3 comprises the support portion 3a, with setting the setting temperature of the heating tool 1 to be approximately 270° C. and setting the setting temperature of the body portion 3b of the backup member 3 to be approximately 80° C., it is possible to heat the anisotropic conductive film 137 for 5 to 6 seconds at approximately 200° C. for each thermocompression bonding process as shown in FIG. 12.

Therefore, as clear from the above-described explanations, the backup member 3 comprising the support portion 3a makes it possible to decrease the setting temperature of the heating tool 1 by approximately 80° C. without changing the setting temperature of the body portion 3b of the backup temperature 3 from approximately 80° C.

Moreover, since the support portion 3a of the backup member 3 comprises phenolic resin, it is possible to easily turn the tip surface of the support portion 3a into the flat surface and it is possible to suppress thermal deformation of the support portion 3a.

Furthermore, in a case that the thickness of the support portion 3a of the backup member 3a is set to be within the range of 1 [mm] to 2 [mm], it is possible to effectively decrease heat escaping from the edge of the TFT substrate 111 to the body portion 3b of the backup member 3 and it is possible to effectively suppress the amount of heat to be stored in the support portion 3a increasing.

While the thermocompression bonding apparatus has been used for manufacturing a liquid crystal display apparatus in the above-described embodiment, the thermocompression bonding apparatus can also be used for manufacturing another apparatus (an organic electroluminescence apparatus, for example).

While the heating tool 1 in the above-described embodiment has a heater embedded therein, the heating tool 1 can be configured to not embed the heater. In such a case, the heating tool 1 can be configured to have heat in an external heater conducted to the heating tool 1.

While the heating tool 1 in the above-described embodiment has a rectangular parallelepiped shape, the heating tool 1 can be configured to have a U-letter shape, for example. In other words, the shape of the heating tool 1 is construed to be not limited to the above-described embodiment.

While an electrical connection at the output side end of the output wiring 134 being provided to the source COF 122 is made with the thermocompression bonding apparatus in the above-described embodiment, an electrical connection of the input side end of the input wiring 133 being provided to the source COF 122 can also be made with the above-described thermocompression bonding apparatus. In other words, the terminal of the source signal wiring of the printed substrate 121 and the input side end of the input wiring 133 of the source COF 122 can be electrically connected with the thermocompression bonding apparatus.

While the support portion 3a of the backup member 3 in the above-described embodiment is formed so as to satisfy formulas (1) and (2), it can also be formed so as to satisfy only one of formulas (1) and (2).

In the above-described embodiment, the thickness L of the support portion 3a of the backup member 3 can be set out of the range of 1 [mm] to 2 [mm] in accordance with the material of the support portion 3a.

While the support portion 3a of the backup member 3 is formed with phenolic resin in the above-described embodiment, it can be formed with other heat-resistant plastic, a porous metal or ceramic, for example.

While the specific embodiments of the invention have been described, the invention is construed to be not limited to the above-described embodiments and variations thereof, so that it can be changed variously within the scope of the invention to carry out the invention. For example, an embodiment in which a part of the contents described in the above-described embodiment has been deleted or replaced can be made to be one embodiment of the invention.

In other words, the above-described disclosure can be summarized as follows.

A thermocompression bonding apparatus according to one aspect of the invention is

a thermocompression bonding apparatus to thermocompression bond a second member to be joined 122 to a first member to be joined 111, the thermocompression bonding apparatus comprising:

a heating tool 1 to heat the first member to be joined 111 and the second member to be joined 122, the heating tool 1 comprising a tip 1a to be pressed toward the first and second members to be joined 111, 122;

a cushioning member 2 being arranged between the first and second members to be joined 111, 122 and the tip 1a of the heating tool 1; and

a backup member 3, wherein

the backup member 3 comprises:

a support portion 3a to support the first member to be joined 111 and the second member to be joined 122, the support portion 3a facing the tip 1a of the heating tool 1 via the first member to be joined 111, the second member to be joined 122, and the cushioning member 2; and

a body portion 3b being provided opposite to the first member to be joined 111 and the second member to be joined 122 with respect to the support portion 3a, and

the support portion 3a is formed such that a heat conductivity of the support portion 3a is brought to be less than a heat conductivity of the body portion 3b.

According to the above-described configuration, in a case that the second member to be joined 122 is thermocompression bonded to the first member to be joined 111 via the anisotropic conductive film 137, for example, the tip 1a of the heating tool 1 is pressed toward the first and second members to be joined 111, 122 via the cushioning member 2 to heat the first and second members to be joined 111, 112 and the anisotropic conductive film 137 with the heating tool 1. Here, the support portion 3a of the backup member 3 is positioned between the first and second members to be joined 111, 112 and the body portion 3b of the backup member 3. Moreover, the support portion 3a of the backup member 3 is formed such that the heat conductivity thereof is brought to be less than that of the body portion 3b of the backup member 3. This makes it possible to decrease the amount of heat escaping to the body portion 3b of the backup member 3 from the first and second members to be joined 111, 122. As a result, since the anisotropic conductive film 137 can be heated to the target temperature without increasing the setting temperature of the heating tool 1, it is possible to decrease the setting temperature of the heating tool 1. Therefore, deformation of the heating tool 1 can be suppressed.

Furthermore, in a case that low heat-resistant members 114, 115 are mounted to the first member to be joined 111 or the second member to be joined 122, it is possible to reduce thermal damage of the low heat-resistant members 114, 115 since the setting temperature of the heating tool 1 can be decreased.

In the thermocompression bonding apparatus according to one embodiment,

assuming that a thickness of the support portion 3a is L and the heat conductivity of the support portion 3a is λ, the formula

L/λ≥0.004

is satisfied.

According to the above-mentioned embodiment, in a case that the second member to be joined 122 is thermocompression bonded to the first member to be joined 111 via, for example, the anisotropic conductive film 137, with setting the thickness of the support portion 3a and the heat conductivity of the support portion 3a so as to satisfy L/λ≥0.004, it is possible to surely bring the temperature of the anisotropic conductive film 137 to the target temperature without increasing the time to heat the anisotropic conductive film 137.

In the thermocompression bonding apparatus according to one embodiment, assuming that a thickness of the support portion 3a is L, the heat conductivity of the support portion 3a is λ, a specific heat of the support portion 3a is c, and a density of the support portion 3a is ρ,

Lcρ/λ≤80000

is satisfied.

According to the above-described embodiment, a process to thermocompression bond the second member to be joined 122 to the first member to be joined 111 via the anisotropic conductive film 137, for example, can be carried out a plurality of times. In this case, with setting the thickness L of the support portion 3a, the heat conductivity λ of the support portion 3a, the specific heat c of the support portion 3a, and the density ρ of the support portion 3a so as to satisfy Lcρ/λ≤80000, it is possible to suppress a continuous temperature increase of the support portion 3a of the backup member 3.

In the thermocompression bonding apparatus according to one embodiment,

the support portion 3a comprises a heat-resistant resin.

According to the above-described embodiment, with forming the support portion 3a with the heat-resistant resin, it is possible to easily turn the tip surface of the support portion 3a into a flat surface and it is possible to suppress thermal deformation of the support portion 3a.

In the thermocompression bonding apparatus according to one embodiment,

the thickness of the support portion 3a falls within a range of 1 mm to 2 mm.

According to the above-mentioned embodiment, with setting the thickness of the support portion 3a to be within the range of 1 mm to 2 mm, it is possible to effectively reduce the amount of heat escaping to the body portion 3b from the first and second member to be joined 111, 122 and it is possible to effectively suppress the amount of heat to be stored in the support portion 3a increasing.
1 Heating tool
1a Tip
2 Cushion sheet
3 Backup member
3a Support portion
3b Body portion
102 Source driver
111 TFT substrate
112 Color filter substrate
113 Liquid crystal layer
114 First polarizing plate
115 Second polarizing plate
116 Sealing material
121 Printed substrate
122 Source COF
137 Anisotropic conductive film
132 Source driver IC
131 Film base material
133 Input wiring
134 Output wiring

1. A thermocompression bonding apparatus to thermocompression bond a second member to be joined to a first member to be joined, the thermocompression bonding apparatus comprising:
a heating tool to heat the first member to be joined and the second member to be joined, the heating tool comprising a tip to be pressed toward the first and second members to be joined;
a cushioning member being arranged between the first and second members to be joined and the tip of the heating tool; and
a backup member, wherein
the backup member comprises:
a support portion to support the first member to be joined and the second member to be joined, the support portion facing the tip of the heating tool via the first member to be joined, the second member to be joined, and the cushioning member; and
a body portion being provided opposite to the first member to be joined and the second member to be joined with respect to the support portion,
the support portion is formed such that a heat conductivity of the support portion is brought to be less than a heat conductivity of the body portion, and
assuming that a thickness of the support portion is L and the heat conductivity of the support portion is λ, the formula
L/λ≥0.004
is satisfied.

2. (canceled)

3. The thermocompression bonding apparatus according to claim 1, wherein
assuming that a thickness of the support portion is L, the heat conductivity of the support portion is λ, a specific heat of the support portion is c, and a density of the support portion is ρ,
Lcρ/λ≤80000
is satisfied.

4. The thermocompression bonding apparatus according to claim 1, wherein
the support portion comprises a heat-resistant resin.

5. The thermocompression bonding apparatus according to claim 1, wherein
a thickness of the support portion falls within a range of 1 mm to 2 mm.

6. The thermocompression bonding apparatus according to claim 1, wherein
the support portion is fixed to the tip surface of the body portion.

7. The thermocompression bonding apparatus according to claim 1, further comprising:
a first heater to control a temperature of the heating tool; and
a second heater to control a temperature of the body portion of the backup member.

8. A method of manufacturing a display apparatus using the thermocompression bonding apparatus according to claim 7, the method comprising:
a step of thermocompression bonding, via an anisotropic conductive film, a film base material being the second member to be joined to a substrate to be provided to the display apparatus, the substrate being the first member to be joined, wherein,
in the step of thermocompression bonding, the temperature of the heating tool and the temperature of the body portion of the backup member are controlled using the first heater and the second heater to maintain, for a predetermined time, the state in which a temperature of the anisotropic conductive film is brought to be a predetermined temperature.

9. The method of manufacturing the display apparatus according to claim 8, wherein
the step of thermocompression bonding is repeatedly carried out a plurality of times.

10. The method of manufacturing the display apparatus according to claim 8, wherein
the predetermined temperature is greater than or equal to 200° C. and less than or equal to 220° C.;
the predetermined time is within a range of 5 seconds to 6 seconds; and
a setting temperature of the heating tool is less than 350° C.

11. The method of manufacturing the display apparatus according to claim 10, wherein
the setting temperature of the heating tool is less than or equal to 300° C.; and
a setting temperature of the body portion of the backup member is less than or equal to 100° C.
